(19) United States
(12) Patent Application Publication
(10) Pub. No.: US 2026/0040594 A1
(43) Pub. Date: Feb. 5, 2026

(54) DIODES WITH STRAIGHT SEGMENT ANODES

(71) Applicant: MACOM Technology Solutions Holdings, Inc., Lowell, MA (US)

(72) Inventors: Timothy Edward Boles, Tyngsboro, MA (US); James Joseph Brogle, Merrimac, MA (US); Andrzej Rozbicki, Saratoga, CA (US); Belinda Simone Edmee Piernas, Mason, NH (US); Daniel Gustavo Curcio, Nashua, NH (US); David Russell Hoag, Walpole, MA (US)

(21) Appl. No.: 19/355,547

(22) Filed: Oct. 10, 2025

Related U.S. Application Data
(62) Division of application No. 17/396,244, filed on Aug. 6, 2021.
Application No. 17/396,244 is a continuation-in-part of application No. PCT/US2020/017226, filed on Feb. 7, 2020.
(60) Provisional application No. 62/802,397, filed on Feb. 7, 2019.

(51) Int. Cl. H10D 8/50; H10D 8/01; H10D 62/10; H10D 62/824; H10D 62/854

(52) U.S. Cl. CPC H10D 8/50; H10D 8/053; H10D 62/117; H10D 62/824; H10D 62/854

(57) ABSTRACT

A diode structure is described. In one example, a diode structure includes an N-type layer of gallium arsenide (GaAs) semiconductor material comprising a first dopant, an intrinsic layer of GaAs semiconductor material formed on the N-type layer, and a P-type layer of GaAs semiconductor material comprising a second dopant and being formed on the intrinsic layer. A top surface perimeter of the P-type layer includes a width W and a length L. An aspect ratio of the P-type layer is defined as a ratio of W and L, and W is greater than L or L is greater than W such that the aspect ratio of the P-type layer is 2 or greater. In other aspects, the top surface perimeter of the of the P-type layer includes a first straight portion, a first semi-ring-shaped portion, a second semi-ring-shaped portion, and a second straight portion.

### CROSS-REFERENCE TO RELATED APPLICATIONS

This application is a divisional of U.S. Non-Provisional patent application Ser. No. 17/396,244, titled “Diodes with Straight Segment Anodes,” filed Aug. 6, 2021, which is a continuation-in-part of PCT Application No. PCT/US2020/017226, filed Feb. 7, 2020, titled “Diodes with Straight Segment Anodes,” which claims the benefit of and priority to U.S. Provisional Application No. 62/802,397, filed Feb. 7, 2019, the entire contents of each of which application is hereby incorporated herein by reference.

### BACKGROUND

A PIN (P-type-Intrinsic-N-type) diode is a diode with an undoped intrinsic semiconductor region between a P-type semiconductor region and an N-type semiconductor region. PIN diodes can be fabricated by the growth, deposition, or other placement of layers vertically on a substrate. The P-type and N-type regions are typically heavily doped because they are used for ohmic contacts. The top, P-type region is the anode of the PIN diode, and the bottom, N-type region or substrate is the cathode of the PIN diode. The inclusion of the intrinsic region between the P-type and N-type regions is in contrast to an ordinary PN diode, which does not include an intrinsic region. When unbiased, the PIN diode is in a high impedance state and can be represented as a capacitor.

If a positive voltage larger than a threshold value is applied to the anode with respect to the cathode of a PIN diode, a current will flow through the PIN diode and the impedance will decrease. A PIN diode in a forward biased state can be represented as a resistor whose value decreases to a minimum value as the current through the PIN diode increases. The bias to change the PIN diode from the high impedance (off) state to the low impedance (on) state can be a direct or alternating current bias. The magnitude of the bias must, in any case, be greater than the threshold value of the PIN diode, and the duration must be longer than the transit time of carriers across the intrinsic region of the PIN diode, for the PIN diode to enter the low impedance state.

### SUMMARY

A number of diode structures are described. An example PIN diode structure includes an N-type layer of gallium arsenide semiconductor material including a first dopant, an intrinsic layer of gallium arsenide semiconductor material formed on the N-type layer, and a P-type layer of gallium arsenide semiconductor material including a second dopant and formed on the intrinsic layer. A top surface perimeter of the P-type layer includes a width W and a length L. An aspect ratio of the P-type layer is defined as a ratio of W and L, and W is greater than L or L is greater than W such that the aspect ratio of the P-type layer is two or greater. In one implementation, the top surface perimeter of the P-type layer includes a first straight portion, a first semi-ring-shaped portion, a second semi-ring-shaped portion, and a second straight portion.

In other aspects, the P-type layer may include a P-type layer of aluminum gallium arsenide semiconductor material. The P-type layer may include an anode of the PIN diode structure, and the N-type layer may include a cathode of the PIN diode structure. The aspect ratio of the P-type layer may be three or greater, and in other forms, four or greater. The first dopant may include silicon, and the second dopant may include carbon. A substrate may be included, and the N-type layer, intrinsic layer, and P-type layer may be formed on the substrate.

In other aspects, the first straight portion and first semi-ring-shaped portion may be mirrored as compared to the second semi-ring-shaped portion and second straight portion. A length of the first semi-ring-shaped portion may differ from a length of the second semi-ring-shaped portion, and a length of the first straight portion may differ from a length of the second straight portion.

Another example diode structure includes an anode layer of aluminum gallium arsenide semiconductor material of a first doping type, a cathode layer of gallium arsenide semiconductor material of a second doping type, and an intrinsic layer of gallium arsenide semiconductor material between the anode layer and the cathode layer. A top surface perimeter of the anode layer includes a first straight portion and a first curved portion.

In other aspects, the top surface perimeter of the anode layer may include the first straight portion, the first curved portion, a second straight portion, and a second curved portion. The first straight portion and first curved portion may be mirrored as compared to the second curved portion and second straight portion. The top surface perimeter of the anode layer may include a width W and a length L, and an aspect ratio of the anode layer may be defined as a ratio of W and L. W may be greater than L or L may be greater than W such that the aspect ratio of the anode layer is two or greater. The aspect ratio of the anode layer may be three or greater. The anode layer may include a P-type layer of aluminum gallium arsenide semiconductor material, and the cathode layer may include an N-type layer of gallium arsenide semiconductor material.

Another example diode structure includes an anode layer of semiconductor material of a first doping type, a cathode layer of semiconductor material of a second doping type, and an intrinsic layer of semiconductor material between the anode layer and the cathode layer. A top surface perimeter of the anode layer includes a first straight portion and a first curved portion.

In other aspects, the top surface perimeter of the anode layer may include the first straight portion, the first curved portion, a second straight portion, and a second curved portion. The top surface perimeter of the anode layer may include a width W and a length L, and an aspect ratio of the anode layer may be defined as a ratio of W and L. W may be greater than L or L may be greater than W such that the aspect ratio of the anode layer is two or greater. The anode layer may include a P-type layer of aluminum gallium arsenide semiconductor material, and the cathode layer may include an N-type layer of gallium arsenide semiconductor material.

### BRIEF DESCRIPTION OF THE DRAWINGS

Aspects of the present disclosure can be better understood with reference to the following drawings. It is noted that the elements in the drawings are not necessarily to scale, with emphasis instead being placed upon clearly illustrating the principles of the embodiments. In the drawings, like reference numerals designate like or corresponding, but not necessarily the same, elements throughout the several views.

FIG. 1 illustrates an example PIN diode structure having a round anode according to various embodiments described herein.

FIG. 2A illustrates a perspective view of an example PIN diode structure having a square-shaped anode according to various embodiments described herein.

FIG. 2B illustrates a cross-sectional view of the PIN diode structure shown in FIG. 2A according to various embodiments described herein.

FIG. 3 is a chart illustrating the thermal resistance versus diode area for example PIN diodes having circular and rectangular anodes according to various embodiments described herein.

FIG. 4 illustrates an example PIN diode structure having a rectangular-shaped anode according to various embodiments described herein.

FIG. 5 is a chart illustrating the series resistance versus diode area for example PIN diodes having circular and rectangular anodes according to various embodiments described herein.

FIG. 6A illustrates examples of other shapes of anodes for diodes according to various embodiments described herein.

FIG. 6B illustrates additional examples of other shapes of anodes for diodes according to various embodiments described herein.

FIG. 7 illustrates an example method of fabrication of diode structures according to various embodiments described herein.

### DETAILED DESCRIPTION

PIN diodes are often used as switching elements in a variety of applications. Such applications include radiation imaging, radar applications, and switch matrixes for networking applications, among others. PIN diodes used in those radio frequency and microwave applications can be fabricated as homojunction devices and used in frequency ranges from about one megahertz (MHz) to well above one hundred gigahertz (GHz) or higher.

As an example, a PIN diode is operable as high frequency switch by operating effectively as a high frequency resistor. It is possible to modify the resistance of the intrinsic region by many orders of magnitude as a function of the application of a direct current bias to the PIN diode. More particularly, when the PIN diode is in the “off” state, the diode operates as an electrical open, such that coupling occurs only through capacitance. Accordingly, by making the capacitance small, coupling is minimal at high frequencies. Thus, the smaller the capacitance, the greater the high frequency impedance of the device. This represents the operation of the device in the isolation mode. However, when the device is in the “on” state, current must be conducted through the device, thus necessitating the need for reduced series resistance.

The performance characteristics of PIN switching diodes are limited in part by parameters such as insertion loss and isolation. Insertion loss is related to the ratio of the output signal power from a diode relative to the input signal power when the series-measured diode is in the “on” state. Isolation is related to the ratio of the output signal power from the diode relative to the input signal power when the series-measured diode is in the “off” state. Thus, depending upon the particular application for use of PIN diodes, a significant consideration in the design of the PIN diodes is to reduce insertion loss without compromising isolation. Another aim is to decrease the resistance of the diode by increasing the carrier concentration in the intrinsic region.

To address some of the concerns identified above, Aluminum Gallium Arsenide (AlGaAs) and Gallium Arsenide (GaAs) heterojunction PIN diodes, such as those described in U.S. Pat. Nos. 6,794,734 and 7,049,181, both of which are hereby incorporated herein by reference in their entirety, were developed. Before that time, PIN diodes were fabricated from single-crystal homojunction elemental and compound semiconductors, such as Germanium (Ge), Silicon (Si), SiGe, Indium Phosphide (InP), etc. By increasing the bandgap of the anode and/or the cathode through the introduction of Al to the GaAs layer, for example, the injection and confinement of carriers in the intrinsic region was enhanced under forward bias, while the physical dimensions of the depletion region under reverse bias remained unchanged. The increased concentration of intrinsic region carriers resulted in reduced high frequency resistance of a forward biased diode, while the identical depletion region resulted in an unchanged capacitance of a reverse biased diode.

Example uses for these new types of PIN diodes include monolithic integrated single-pole single-throw (SPST) switches, single-pole double-throw (SPDT) switches, and single pole multi-throw (SPMT) switches employing shunt connected PIN diodes. These switches benefit from reduced reverse bias capacitance, without undesirably increasing the series resistance within the intrinsic region of the diode. Series diode configurations benefit from reduced series resistance but without an undesirable increase in diode capacitance. Other series-shunt, all-series, and all-shunt designs were also presented with low insertion loss and high isolation. Other types of multi-throw AlGaAs PIN diode switches were subsequently developed with improved characteristics.

Current discrete PIN diode and other diode-based single-function Monolithic Microwave Integrated Circuits (MMIC's) have design layouts with round anodes. Round anodes have been selected, in part, to prevent premature field build up (particularly at corners of the anodes) and reduce reverse breakdown voltages. While the use of round anodes resulted in reduced peak fields, the effect of the circular shape of the anodes on the optimization of other device operating parameters, such as thermal resistance, power handling, and series resistance, were essentially ignored.

In existing AlGaAs PIN diodes, the P+ anode is designed using a layout of round structures/shapes to produce the p-type diode junction. This round configuration of the anode is then transferred through subsequent wafer fabrication processes to the underlying intrinsic region, and the N+ cathode. The technical reason for this round shape/configuration was, originally, to maximize reverse avalanche breakdown for each intrinsic region thickness and anode diameter. However, while this round shape is helpful to maximize breakdown voltages, the optimization of other key device design parameters, such as thermal resistance, electrical on-resistance, and power handling capabilities, were essentially ignored.

From a thermal perspective, in particular, forming a PIN diode with a round anode may be a poor choice. Forming AlGaAs PIN diodes with quadrilateral-shaped (e.g., square- or rectangular-shaped) anodes results in a significant improvement in thermal characteristics. Approximately 400% better thermal resistance can be achieved compared to standard round designs having a constant anode area and corresponding constant device capacitance. The improvements in thermal characteristics can be shown using the straightforward, simple heat spreading model described below.

Similarly, the on-resistance of AlGaAs PIN diodes with square- or rectangular-shaped anodes can be modeled using an electrical spreading model that accounts for high frequency effects due to electrical skin depth limitations. As discussed herein, the electrical on-resistance for a rectangular AlGaAs PIN diode can be reduced by approximately 200% as compared to the standard circular PIN diode designs.

Both these thermal resistance and electrical on-resistance improvements in AlGaAs PIN diodes can translate to increased power handling when the diodes are employed in control function applications, such as high frequency switches, limiters, and attenuators, among others. The increase in power handling is a direct result of the ability of the rectangular diodes to both remove heat from the diode structure and to maintain a low operating junction temperature. The increase is also a direct result of the reduction of the fundamental dissipative loss due to the lower device on-resistance within the AlGaAs PIN diode junction.

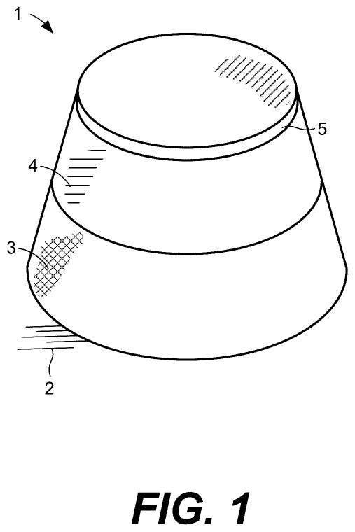

Turning to the drawings, FIG. 1 illustrates an example PIN diode structure 1 (“PIN diode structure 1”) having a round anode. The PIN diode structure 1 includes an N+ semiconductor material layer 3 (“N+ layer 3”) on a substrate 2 of semiconductor material, an intrinsic layer 4 on a top surface of the N+ layer 3, and a P+ semiconductor material layer 5 (“P+ layer 5”) on a top surface of the intrinsic layer 4. The P+ layer 5 forms an anode layer of the PIN diode structure 1, and one or more ohmic metal contacts can be disposed on the P+ layer 5. The N+ layer 3 forms a cathode layer of the PIN diode structure 1, and one or more ohmic metal contacts can be disposed on the N+ layer 3.

As shown in FIG. 1, the PIN diode structure 1 is designed using a layout of round or circular structures/shapes to produce the diode junctions among the N+ layer 3, the intrinsic layer 4, and the P+ layer 5. The round or circular perimeter of the P+ layer 5 is transferred through subsequent wafer fabrication processes to the underlying intrinsic layer 4, and to the N+ layer 3. This round shape/configuration was originally selected to maximize reverse avalanche breakdown. However, while this round shape is helpful to maximize breakdown voltages, the optimization of other key device design parameters, such as thermal resistance, electrical on-resistance, and power handling capabilities, were essentially ignored with the design shown in FIG. 1. Thus, PIN diode structures designed using square-shaped, rectangular-shaped, and other layout shapes of are also described herein.

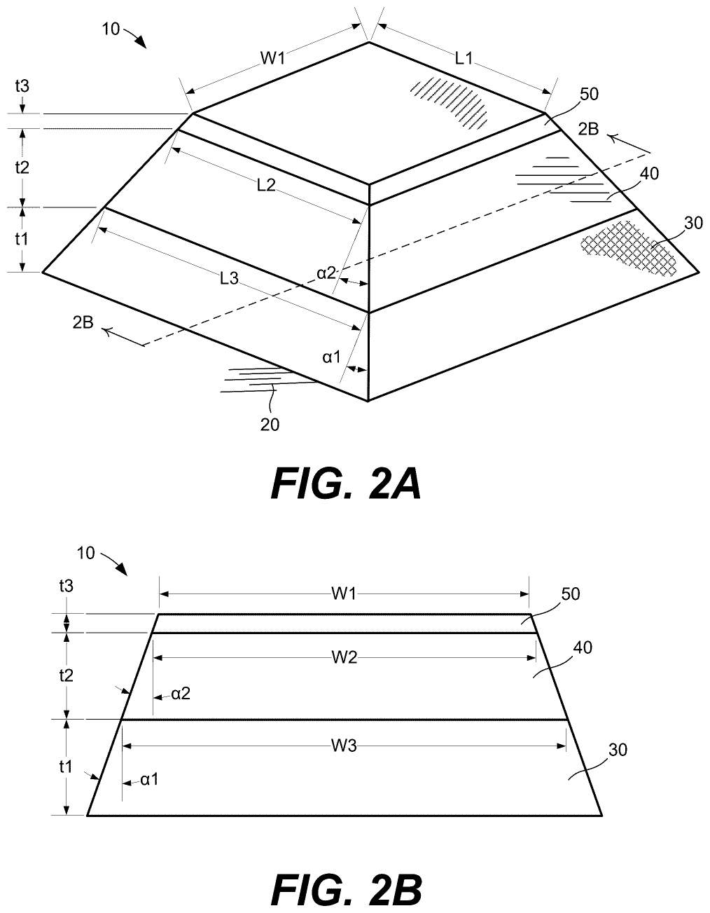

FIG. 2A illustrates a perspective view of an example PIN diode structure 10 having a square-shaped anode according to various embodiments described herein. FIG. 2B illustrates a cross-sectional view of the PIN diode structure 10. The PIN diode structure 10 is provided as representative example in FIGS. 2A and 2B for discussion. The shapes, sizes, and relative sizes of the various layers of the PIN diode structure 10 are not necessarily drawn to scale. The layers shown in FIGS. 2A and 2B are not exhaustive, and the PIN diode structure 10 can include other layers and elements not separately illustrated.

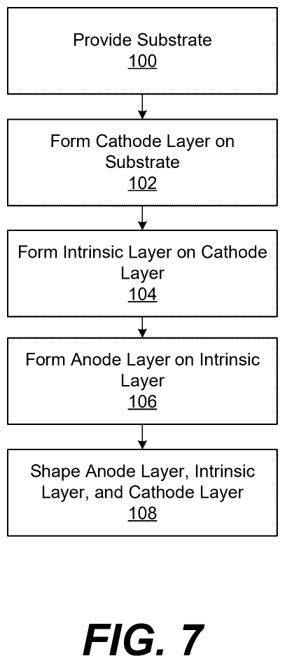

The PIN diode structure 10 can be formed as part of a larger integrated circuit device in combination with other diodes, capacitors, inductors, resistors, and layers of metal to electrically interconnect the circuit elements together to form switches, limiters, and other devices. Additionally, although the PIN diode structure 10 is described as being formed on a GaAs substrate, with layers of doped GaAs and AlGaAs, the concepts described herein are not limited to PIN diodes formed from any particular type(s) of semiconductor materials. Instead, the use of anodes having square, rectangular, curved, horseshoe, S-curve, or other shapes, in extension to round or circular shapes, can be applied to PIN diodes formed from other type(s) of semiconductor materials to achieve advantages similar to those described herein. Moreover, the concepts described herein can also be applied to fabricate NIP diodes, and combinations of NIP diodes with various components in a monolithic circuit format suitable for microwave circuit applications. A method of fabricating or manufacturing the PIN diode structure 10, among others, is described in detail below with reference to FIG. 7.

Referring between FIGS. 2A and 2B, the PIN diode structure 10 can be formed upon a substrate 20 of semiconductor material. The substrate 20 provides a surface upon which the remaining layers of the PIN diode structure 10 can be formed, for fabrication, but the substrate 20 does not provide an active layer in the PIN diode structure 10. The substrate 20 can be embodied as any suitable semiconductor material, such as a GaAs or another suitable semiconductor substrate.

The PIN diode structure 10 includes an N+ layer 30 on a top surface of the substrate 20. N+ layer 30 forms a cathode layer of the PIN diode structure 10. Although not shown, one or more n-type ohmic metal contacts can be formed or disposed on the N+ layer 30 to provide contacts in a manner similar to that shown in U.S. Pat. Nos. 6,794,734 and 7,049,181, for example. In one embodiment, the N+ layer 30 can be formed as GaAs semiconductor material that has been sufficiently doped with a first dopant. The first dopant can be Silicon (Si), for example, or another N+ dopant. In another example, the N+ layer 30 can be formed as AlGaAs semiconductor material that has been sufficiently doped with the first dopant. The PIN diode structure 10 can include one or two heterojunction interfaces with the intrinsic layer 40 depending upon whether or not the N+ layer 30 is formed from GaAs or AlGaAs semiconductor material, as further described below.

The PIN diode structure 10 also includes an intrinsic layer 40 on a top surface of the N+ layer 30. The intrinsic layer 40 will establish the breakdown voltage and the capacitance of the PIN diode structure 10, at least in part. The intrinsic layer 40 can be formed as GaAs semiconductor material on a top surface of the N+ layer 30. The GaAs semiconductor material can be intrinsic, not doped, or not intentionally doped (i.e., without any dopant being intentionally added during the process step of forming).

The PIN diode structure 10 also includes a P+ layer 50 on a top surface of the intrinsic layer 40. The P+ layer 50 forms an anode layer of the PIN diode structure 10. Although not shown, one or more p-type ohmic metal contacts can be disposed on the P+ layer 50 to form the anode contact of the PIN diode structure 10. In one embodiment, the P+ layer 50 can be formed as GaAs semiconductor material that has been sufficiently doped with a second dopant. The second dopant can be Carbon (C), for example, or another P+ dopant. In another example, the P+ layer 50 can be formed as AlGaAs semiconductor material that has been sufficiently doped with the second dopant. The PIN diode structure 10 can include one or two heterojunction interfaces with the intrinsic layer 40 depending upon whether or not the P+ layer 50 is formed from GaAs or AlGaAs semiconductor material. In one preferred embodiment, the PIN diode structure 10 includes one heterojunction interface with the intrinsic layer 40, with the N+ layer 30 being formed from GaAs semiconductor material and the P+ layer 50 being formed from AlGaAs semiconductor material.

As shown in FIGS. 2A and 2B, the N+ layer 30 is formed at a thickness “t1,” and the intrinsic layer 40 is formed at a thickness “t2.” In one example, the N+ layer 30 is formed at a thickness of 2 μm, and the intrinsic layer 40 is formed at a thickness of 2 μm. However, the thickness of the N+ layer 30 and the thickness of the intrinsic layer 40 can vary from that example to meet certain device characteristics. The P+ layer 50 is also formed at a thickness “t3,” which can be 0.8 μm in one example. The thickness of the P+ layer 50 can vary from that example to meet certain device characteristics. The thicknesses of each of the layers 30, 40, and 50 can be selected and optimized as design parameters of the PIN diode structure 10.

Further, “α1” is the spread angle of the N+ layer 30, and “α2” is the spread angle of the intrinsic layer 40. As shown in FIGS. 2A and 2B, the spread angle “α1” of the N+ layer 30 is measured from a side surface of the N+ layer 30 to a line or plane orthogonal to the top surface of the N+ layer 30. Similarly, the spread angle “α2” of the intrinsic layer 40 is measured from a side surface of the intrinsic layer 40 to a line or plane orthogonal to the top surface of the intrinsic layer 40. The spread angle of the P+ layer 50 is not expressly identified in FIGS. 2A and 2B, but is also defined or measured from a side surface of the P+ layer 50 to a line or plane orthogonal to the top surface of the P+ layer 50. The spread angles of each of the layers 30, 40, and 50 in the PIN diode structure 10 can be varied as compared to each other and other PIN diode structures to optimize design parameters of the PIN diode structure 10.

As shown in FIGS. 2A and 2B, each of the layers 30, 40, and 50 has a width and a length. The top surface of the P+ layer 50 is shaped as a regular quadrilateral, with four equal, straight sides and four right angles. The width “W1” of the top surface of the P+ layer 50 is the same or substantially the same (i.e., within manufacturing tolerances) as the length “L1” of the P+ layer 50. The sides of the P+ layer 50 are straight or substantially straight (i.e., within manufacturing tolerances), and the sides of the P+ layer 50 intersect with each other to form right angles (i.e., within manufacturing tolerances) at corners of the top surface of the P+ layer 50. Thus, the PIN diode structure 10 has a square-shaped anode, and the aspect ratio (i.e., “W1”/“L1” or “W1”:“L1”) of the PIN diode structure 10 is (1:1), because the width “W1” of the top surface of the P+ layer 50 is the same as the length “L1” of the P+ layer 50. Similarly, the top surface of the intrinsic layer 40 is square-shaped, as the width “W2” of the top surface of the intrinsic layer 40 is the same or substantially the same as the length “L2” of the intrinsic layer 40. Additionally, the top surface of the N+ layer 30 is square-shaped, as the width “W3” of the top surface of the N+ layer 30 is the same or substantially the same as the length “L3” of the N+ layer 30. Thus, the PIN diode structure 10 has a square-shaped cathode with an aspect ratio of (1:1).

As compared to the PIN diode structure 10 shown in FIG. 2, the PIN diode structure 1 shown in FIG. 1 has circular-shaped anode and a circular-shaped cathode. The perimeter dimensions of the anode and cathode of the PIN diode structure 1 can be defined by a single measurement of the diameter of the anode. Thus, the definition of aspect ratio according to width versus length does not directly apply to the PIN diode structure 1. However, the aspect ratio of the PIN diode structure 1 can be considered (1:1).

The width “W1” of the top surface of the P+ layer 50 and the length “L1” of the P+ layer 50 can each be selected and optimized as design parameters of the PIN diode structure 10 as described herein. For example, particularly as compared to a PIN diode with a round anode, the width “W1” of the top surface of the P+ layer 50, the length “L1” of the P+ layer 50, and the aspect ratio of the anode of the PIN diode structure 10 (i.e., “W1”/“L1”) can be optimized for one or more of thermal resistance, series resistance, electrical on-resistance, frequency, and bandwidth of operation, among other factors. An increase in aspect ratio beyond (1:1) can further lower thermal resistance, lower series resistance, lower electrical on-resistance, increase bandwidth of operation, and increase power handling capabilities.

The width “W1” of the top surface of the P+ layer 50 is smaller than the width “W2” of the top surface of the intrinsic layer 40, where the bottom surface of the P+ layer 50 interfaces with or contacts the top surface of the intrinsic layer 40. Similarly, the length “L1” of the top surface of the P+ layer 50 is smaller than the length “L2” of the top surface of the intrinsic layer 40, where the bottom surface of the P+ layer 50 interfaces with the top surface of the intrinsic layer 40. Additionally, the width “W2” of the top surface of the intrinsic layer 40 is smaller than the width “W3” of the top surface of the N+ layer 30, where the bottom surface of the intrinsic layer 40 interfaces with the top surface of the N+ layer 30. Further, the length “L2” of the top surface of the intrinsic layer 40 is smaller than the length “L3” of the top surface of the N+ layer 30, where the bottom surface of the intrinsic layer 40 interfaces with the top surface of the N+ layer 30.

In the example shown, the widths and the lengths of the top surfaces of each of the layers 30, 40, and 50 are smaller than the widths and the lengths of the bottom surfaces of each of the layers 30, 40, and 50. The differences in the widths and the lengths between the top and bottom surfaces is a function of and can be calculated using the spread angles of each of the layers 30, 40, and 50. The widths and the lengths of the top and bottom surfaces of each of the layers 30, 40, and 50 (and the spread angles) can also be varied to optimize key design parameters of the PIN diode structure 10.

The P+ layer 50 forms the anode of the PIN diode structure 10. The top and bottom surfaces of the P+ layer 50 of the PIN diode structure 10 in FIG. 2 are formed in the shape of squares rather than circles, as shown for the PIN diode structure 1 in FIG. 1. Similarly, the top and bottom surfaces of the N+ layer 30 and the intrinsic layer 40 are also shaped as squares. A number of operating characteristics of the PIN diode structure 10 are improved as compared to the PIN diode structure 1 due to the use of the square-, rather than round-shaped, features. Particularly, as compared to a round diode anode, one or more of the thermal resistance, the electrical on-resistance, and the overall power handling capabilities of the PIN diode structure 10 can be improved due to the square-shaped anode.

The thermal resistance of the PIN diode structures described herein can be shown to benefit from square- and rectangular-shaped device features. A simple heat spreading model for the PIN diode structures is provided below, referencing the dimensions of PIN diode structure 10 as an example. For the model, the anode or top of the P+ layer 50 can be assumed a heat source and the cathode or bottom of the N+ layer 30 can be assumed a heat sink. As a single layer solution, the thermal resistance, By, of one layer of the PIN diode structure 10 is provided by the following simple heat spreading model:

$${θ}_{j c} = ( \frac{{t}_{1}}{{k}_{1}} ) ( \frac{1}{( {W}_{1} * {L}_{1} ) + ( {W}_{1} * {t}_{1} * TAN ( {α}_{1} ) ) + ( {L}_{1} * {t}_{1} * TAN ( {x}_{1} ) ) + ( 2 * {( {t}_{1} )}^{2} * {( TAN ( {α}_{1} ) )}^{2} )} ) , \qquad ( 1 )$$

where t₁ is the thickness of the layer, α₁ is the spread angle of the layer, W₁ is the width at the top of the layer, and L₁ is the length at the top of the layer.

As a two layer solution, the thermal resistance, By, of two layers of the PIN diode structure 10 is provided by the following simple heat spreading model:

$${θ}_{j c} = ( \frac{2 * {t}_{1}}{{k}_{1}} ) ( \frac{1}{( {W}_{1} * {L}_{1} ) + ( ( {W}_{1} + ( 2 * {t}_{1} * TAN ( {α}_{1} ) ) ) * ( {L}_{1} + ( 2 * {t}_{1} * TAN ( {α}_{1} ) ) ) )} ) + ( \frac{2 * {t}_{2}}{{k}_{2}} ) ( \frac{1}{( {W}_{2} * {L}_{2} ) + ( ( {W}_{2} + ( 2 * {t}_{2} * TAN ( {α}_{2} ) ) ) * ( {L}_{2} + ( 2 * {t}_{2} * TAN ( {α}_{2} ) ) ) )} ) , \qquad ( 2 )$$

where t₁ and t₂ are the thicknesses of the first and second layers, respectively, α₁ and α₂ are the spread angles of the first and second layers, respectively, W₁ is the width at the top of the first layer, L₁ is the length at the top of the first layer, and

$$\begin{matrix}{W}_{2} = {W}_{1} + ( 2 * {t}_{1} * TAN ( {α}_{1} ) ) , and \\ {L}_{2} = {L}_{1} + ( 2 * {t}_{1} * TAN ( {α}_{1} ) ) .\end{matrix} \qquad ( 3 )$$

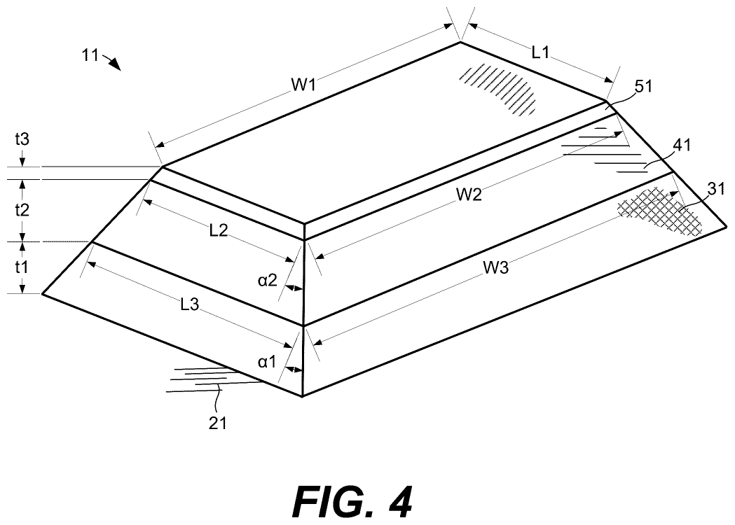

The simple heat spreading models outlined above can also be applied as models for other PIN diodes, including the PIN diode structure 11 shown in FIG. 4, as described below.

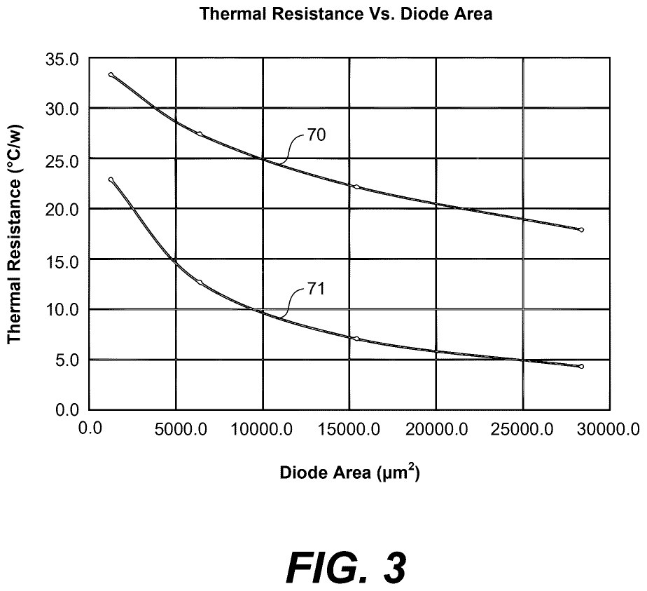

For an equivalent top surface unit area, the shortest possible perimeter of an anode is a circular perimeter. This relatively short perimeter also results in a higher thermal resistance as compared to a longer perimeter. The higher thermal resistance can be less desirable in many applications. FIG. 3 is a chart illustrating the thermal resistance versus diode area for example PIN diodes having circular and rectangular anodes according to various embodiments described herein. The curve 70 identifies thermal resistance versus diode for PIN diodes having circular anodes. The curve 71 identifies thermal resistance versus diode for PIN diodes having rectangular anodes. As shown in FIG. 3, the thermal resistance of PIN diodes having rectangular anodes is significantly less than the thermal resistance of PIN diodes having circular anodes. Thus, PIN diodes having rectangular anodes are relatively easier to cool and less susceptible to adverse operating characteristics due to high operating temperatures.

The embodiments described herein are not limited to square-shaped anodes, however, as rectangular-shaped anodes are also within the scope of the disclosure. FIG. 4 illustrates a perspective view of an example PIN diode structure 11 having a rectangular-shaped anode according to various embodiments described herein. The PIN diode structure 11 is provided as a representative example in FIG. 4 for discussion. The shapes, sizes, and relative sizes of the various layers of the PIN diode structure 11 are not necessarily drawn to scale. The layers shown in FIG. 4 are not exhaustive, and the PIN diode structure 11 can include other layers and elements not separately illustrated. Additionally, the PIN diode structure 11 can be formed as part of a larger integrated circuit device in combination with other diodes, capacitors, inductors, resistors, and layers of metal to electrically interconnect the circuit elements together to form switches, limiters, and other devices.

The PIN diode structure 11 can be formed as part of a larger integrated circuit device in combination with other diodes, capacitors, inductors, resistors, and layers of metal to electrically interconnect the circuit elements together to form switches, limiters, and other devices. Additionally, although the PIN diode structure 11 is described as being formed on a GaAs substrate, with layers of doped GaAs and AlGaAs, the concepts described herein are not limited to PIN diodes formed from any particular type(s) of semiconductor materials. Instead, the use of anodes having square, rectangular, or other shapes, in extension to round or circular shapes, can be applied to PIN diodes formed from other type(s) of semiconductor materials to achieve advantages similar to those described herein. Moreover, the concepts described herein can also be applied to fabricate NIP diodes, and combinations of NIP diodes with various components in a monolithic circuit format suitable for microwave circuit applications. A method of fabricating or manufacturing the PIN diode structure 11, among others, is described in detail below with reference to FIG. 7.

Referring to FIG. 4, the PIN diode structure 11 can be formed upon a substrate 21 of semiconductor material. The substrate 21 provides a surface upon which the remaining layers of the PIN diode structure 11 can be formed, for fabrication, but the substrate 21 does not provide an active layer in the PIN diode structure 11. The substrate 21 can be embodied as any suitable semiconductor material, such as a GaAs or another suitable semiconductor substrate.

The PIN diode structure 11 includes an N+ layer 31 on a top surface of the substrate 21. N+ layer 31 forms a cathode layer of the PIN diode structure 11. Although not shown, one or more n-type ohmic metal contacts can be formed or disposed on the N+ layer 30 to provide contacts in a manner similar to that shown in U.S. Pat. Nos. 6,794,734 and 7,049,181, for example. In one embodiment, the N+ layer 31 can be formed as GaAs semiconductor material that has been sufficiently doped with Si. In another example, the N+ layer 31 can be formed as AlGaAs semiconductor material that has been sufficiently doped with Si. The PIN diode structure 11 can include one or two heterojunction interfaces with the intrinsic layer 41 depending upon whether or not the N+ layer 31 is formed from GaAs or AlGaAs semiconductor material, as further described below.

The PIN diode structure 11 also includes an intrinsic layer 41 on a top surface of the N+ layer 31. The intrinsic layer 41 will establish the breakdown voltage and the capacitance of the PIN diode structure 11, at least in part. The intrinsic layer 41 can be formed as GaAs semiconductor material on a top surface of the N+ layer 31.

The PIN diode structure 11 also includes a P+ layer 51 on a top surface of the intrinsic layer 41. The P+ layer 51 forms an anode layer of the PIN diode structure 11. Although not shown, one or more p-type ohmic metal contacts can be disposed on the P+ layer 51 to form the anode contact of the PIN diode structure 11. In one embodiment, the P+ layer 51 can be formed as GaAs semiconductor material that has been sufficiently doped with C. In another example, the P+ layer 51 can be formed as AlGaAs semiconductor material that has been sufficiently doped with C. The PIN diode structure 11 can include one or two heterojunction interfaces with the intrinsic layer 41 depending upon whether or not the P+ layer 51 is formed from GaAs or AlGaAs semiconductor material. In one preferred embodiment, the PIN diode structure 11 includes one heterojunction interface with the intrinsic layer 41, with the N+ layer 31 being formed from GaAs semiconductor material and the P+ layer 51 being formed from AlGaAs semiconductor material.

As shown in FIG. 4, the N+ layer 31 is formed at a thickness “t1,” and the intrinsic layer 40 is formed at a thickness “t2.” In one example, the N+ layer 31 is formed at a thickness of 2 μm, and the intrinsic layer 41 is formed at a thickness of 2 μm. However, the thickness of the N+ layer 31 and the thickness of the intrinsic layer 41 can vary from that example to meet certain device characteristics. The P+ layer 51 is also formed at a thickness “t3,” which can be 0.8 μm in one example. The thickness of the P+ layer 51 can vary from that example to meet certain device characteristics. The thicknesses of each of the layers 31, 41, and 51 can be selected and optimized as design parameters of the PIN diode structure 11.

Further, “α1” is the spread angle of the N+ layer 31, and “α2” is the spread angle of the intrinsic layer 41. As shown in FIG. 4, the spread angle “α1” of the N+ layer 31 is measured from a side surface of the N+ layer 31 to a line or plane orthogonal to the top surface of the N+ layer 31. Similarly, the spread angle “α2” of the intrinsic layer 41 is measured from a side surface of the intrinsic layer 41 to a line or plane orthogonal to the top surface of the intrinsic layer 41. The spread angle of the P+ layer 51 is not expressly identified in FIG. 4, but is also defined or measured from a side surface of the P+ layer 51 to a line or plane orthogonal to the top surface of the P+ layer 51. The spread angles of each of the layers 31, 41, and 51 in the PIN diode structure 11 can be varied as compared to each other and other PIN diode structures to optimize design parameters of the PIN diode structure 11.

As shown in FIG. 4, each of the layers 31, 41, and 51 has a width and a length. The top surface of the P+ layer 51 is shaped as a quadrilateral, with straight sides and four right angles. The width “W1” of the top surface of the P+ layer 51 is greater than the length “L1” of the P+ layer 51. Thus, the PIN diode structure 11 has a rectangular-shaped anode. Similarly, the width “W2” of the top surface of the intrinsic layer 41 is greater than the length “L2” of the intrinsic layer 41. The width “W3” of the top surface of the N+ layer 31 is greater than the length “L3” of the N+ layer 31. Thus, the PIN diode structure 11 has a rectangular-shaped features in all layers.

The aspect ratio of the PIN diode structure 11 is greater than (1:1) (i.e., greater than one (1)), because the width “W1” of the top surface of the P+ layer 51 is greater than the length “L1” of the P+ layer 51. The PIN diode structure 11 can have aspect ratios of (1.1:1), (1.2:1), (1.3:1), (1.4:1), as examples, or higher aspect ratios such as (2:1) or two, (3:1) or three, (4:1) or four, (5:1) or five, or greater. The foregoing examples are assumed to be reduced by the greatest common factor between “W1” and “L1”, such that an aspect ratio of (2:1) would be found for both when “W1” is 2 units and “L1” is 1 unit and when “W1” is 4 units and “L1” is 2 units.

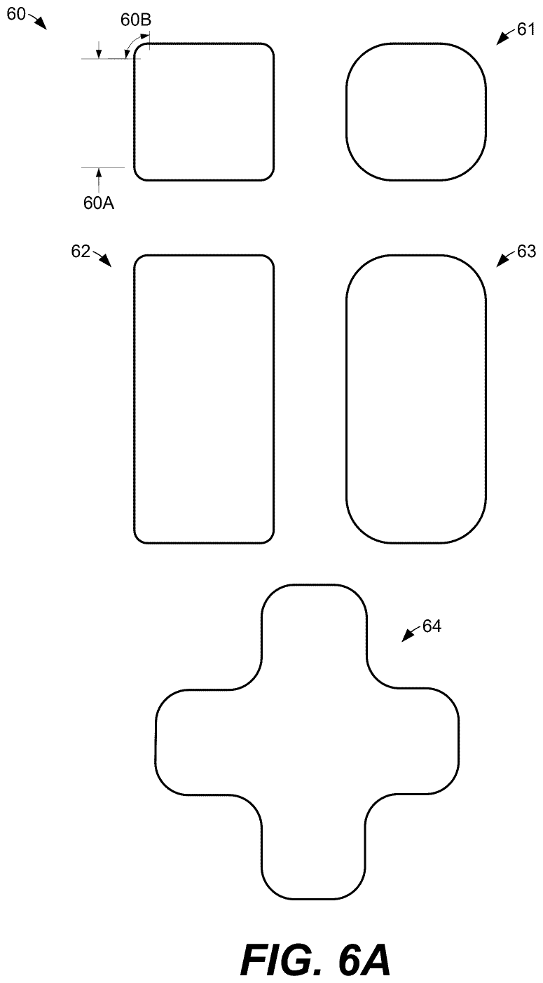

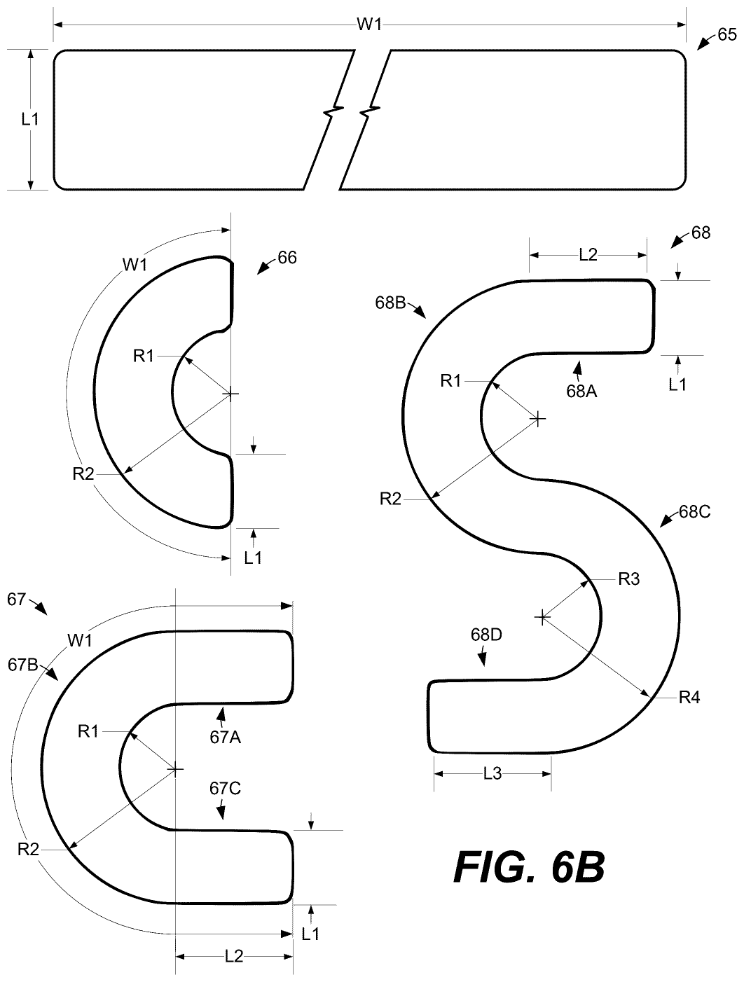

An aspect ratio of greater than one (1) is also achieved for a length “L1” of the P+ layer 51 greater than the width “W1” of the P+ layer 51, as the width “W1” and the length “L1” can be considered interchangeable for consideration of aspect ratios. The PIN diode structure 11 can have aspect ratios of (1:1.1), (1:1.2), (1:1.3), (1:1.4), as examples, or a high aspect ratio such as (1:2), (1:3), (1:4), (1:5), or greater. The PIN diode structure 11 can be considered to have a high aspect ratio when either the width “W1” is at least 4 times or greater than the length “L1” of the P+ layer 51, or when the length “L1” is at least 4 times or greater than the width “W1” of the P+ layer 51. Additional examples of diodes having aspect ratios greater than one (1) are shown in FIGS. 6A and 6B and described below.

However, the width “W1” of the top surface of the P+ layer 51 is smaller than the width “W2” of the top surface of the intrinsic layer 41, where the bottom surface of the P+ layer 51 interfaces with the top surface of the intrinsic layer 40. Similarly, the length “L1” of the top surface of the P+ layer 51 is smaller than the length “L2” of the top surface of the intrinsic layer 41, where the bottom surface of the P+ layer 51 interfaces with the top surface of the intrinsic layer 41. Additionally, the width “W2” of the top surface of the intrinsic layer 41 is smaller than the width “W3” of the top surface of the N+ layer 31, where the bottom surface of the intrinsic layer 41 interfaces with the top surface of the N+ layer 31. Further, the length “L2” of the top surface of the intrinsic layer 41 is smaller than the length “L3” of the top surface of the N+ layer 31, where the bottom surface of the intrinsic layer 41 interfaces with the top surface of the N+ layer 31.

In the example shown, the widths and the lengths of the top surfaces of each of the layers 31, 41, and 51 are smaller than the widths and the lengths of the bottom surfaces of each of the layers 31, 41, and 51. The differences in the widths and the lengths between the top and bottom surfaces is a function of and can be calculated using the spread angles of each of the layers 31, 41, and 51. The widths and the lengths of the top and bottom surfaces of each of the layers 31, 41, and 51 (and the spread angles) can also be varied to optimize key design parameters of the PIN diode structure 11.

The P+ layer 51 forms the anode of the PIN diode structure 11. The top and bottom surfaces of the P+ layer 51 of the PIN diode structure 11 are formed in the shape of rectangles rather than circles, as shown for the PIN diode structure 1. Similarly, the top and bottom surfaces of the N+ layer 31 and the intrinsic layer 41 are also shaped as rectangles. A number of operating characteristics of the PIN diode structure 11 are improved as compared to the PIN diode structure 1 due to the use of the rectangle-, rather than round-shaped, features. Particularly, as compared to a round diode anode, one or more of the thermal resistance, the electrical on-resistance, and the overall power handling capabilities of the PIN diode structure 11 can be improved due to the square-shaped anode.

The effective electrical conductivity/resistivity (e.g., series resistance) of the PIN diode structures described herein can be shown to benefit from square- and rectangular-shaped device features. A simple series resistance model for the PIN diode structures is provided as:

$${R}_{s} = ( \frac{( σ ( f r e q ) * t )}{( W * L ) + ( W * t * TAN ( α ) ) + ( L * t * TAN ( α ) ) + ( 2 * {( t )}^{2} * {( TAN ( α ) )}^{2} )} ) , \qquad ( 4 )$$

where σ(freq) is the operating frequency, t is the thickness of a layer, α is the spread angle of the layer, W is the width at the top of the layer, and L is the length at the top of the layer.

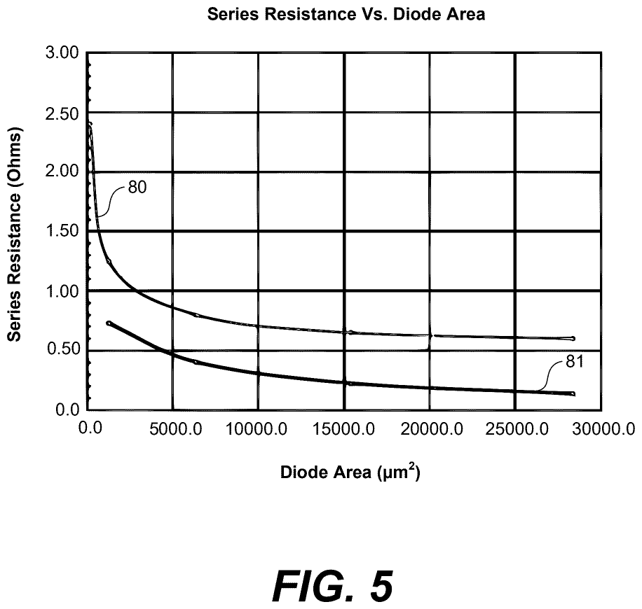

FIG. 5 is a chart illustrating the series resistance versus diode area for example PIN diodes having circular and rectangular anodes according to various embodiments described herein. The curve 80 identifies series resistance versus diode area for PIN diodes having circular anodes. The curve 81 identifies series resistance versus diode area for PIN diodes having rectangular anodes. As shown in FIG. 5, the series resistance of PIN diodes having rectangular anodes are significantly less than the series resistance of PIN diodes having circular anodes.

The embodiments described herein are not limited to square- or rectangular-shaped anodes, however, as square- or rectangular-shaped anodes having rounded corners are also within the scope of the disclosure. As noted above, for an equivalent top surface unit area, the shortest possible perimeter of an anode is a circular perimeter. This relatively short perimeter also results in a higher thermal and series resistance as compared to a longer perimeter. Thus, any shape that contributes to a longer perimeter can result in lower thermal and series resistance as compared to a shorter perimeter.

In that context, FIG. 6A illustrates examples of other shapes of anodes for diodes, from a top-down view, according to various embodiments described herein. As shown, the perimeter of the top surface of the anode 60 is square-shaped but has rounded corners. In that sense, the anode 60 is a quadrilateral-shaped anode formed having a top surface perimeter including a combination of straight side segments, such as straight segment 60A, and round or curved side segments, such as curved segment 60B. The curved segments are relied upon in the anode 60 in place of the right-angled corners in the other examples described herein. The straight and curved segments can be carried to the intrinsic and cathode layers of the diode.

Turning to other examples, the anode 61 is square-shaped but with corners more rounded than the anode 60. The anode 61 is not circular, but approaches a circular shape. Anodes having more or less rounding at the corners are within the scope of the embodiments. Further, the anode 62 is rectangular-shaped but has rounded corners, and the anode 63 is rectangular-shaped but with corners more rounded than the anode 62. The ends of the anode 63 are not half-circles, but approach a half-circle shape. Rectangular-shaped anodes having more or less rounding at the corners, including rectangular-shaped anodes with half-circle endcaps, are within the scope of the embodiments.

Additionally, the anode 64 is generally in the shape of a “+” sign, but with rounded corners. The corners of the anode 64 can be more or less rounded than that shown. Other shapes of anodes are also with in the embodiments, such as anodes generally shaped as trapezoids, stars, bow-ties, and other shapes.

FIG. 6B illustrates additional examples of other shapes of anodes for diodes, from a top-down view. As shown, the anode 65 is rectangle-shaped with rounded corners. The aspect ratio of the anode 65 is relatively high as compared to other examples described herein, as the width “W1” is much longer than the length “L1” of the anode 65. The aspect ratio of the anode 65 can be (2:1), (3:1), (4:1), (5:1), or higher.

The embodiments are not limited to anodes having a relatively high aspect ratios that extend only straight in both the width “W1” and length “L1” dimensions. The embodiments also include anodes having a relatively high aspect ratios that are curved over some sections. For example, the anode 66 is a semi-ring-shaped anode with rounded corners. The width “W1” of the anode 66 is measured along the curved outer perimeter of the anode 66 in the example shown. The length “L1” of the anode 66 is measured along the straight end of the anode 66, such that the length “L1” is substantially equivalent to the difference between the inner radius “R1” and outer radius “R2” of the anode 66.

The aspect ratio of the anode 66 can be (4:1), (5:1), (6:1), (7:1), or higher. The aspect ratio of the anode 66 can vary on the basis of both the inner radius “R1” and outer radius “R2” of the anode 66. For example, an increase of the outer radius “R2” without a corresponding increase of the inner radius “R1” will result in a decreased aspect ratio. On the other hand, an increase of the inner radius “R1” without a corresponding increase of the outer radius “R2” will result in an increased aspect ratio. The use of the semi-ring shape for the anode 66 shown in FIG. 6B can increase the aspect ratio of the anode 66 by a relatively larger factor than an increase in one dimension, measured linearly.

Anode 67 is a horseshoe-shaped anode with rounded corners. The anode 67 includes a first straight portion 67A, a semi-ring-shaped portion 67B, and a second straight portion 67C. The width “W1” of the anode 67 is measured along the outer perimeter of the anode 67 in the example shown. The length “L1” of the anode 67 is measured along the straight end of the anode 67, such that the length “L1” is substantially equivalent to the difference between the inner radius “R1” and outer radius “R2” of the anode 67.

The aspect ratio of the anode 67 can be in a range between (10:1) to (20:1), or higher. The aspect ratio of the anode 67 can vary on the basis of both the inner radius “R1” and outer radius “R2” of the anode 66, as described above with reference to the anode 66. Additionally, the lengths of the first straight portion 67A, the second straight portion 67C, or both can vary as compared to that shown. The straight portions 67A and 67C are shown to be the same length “L2” in FIG. 6B, but the length of the straight portion 67A can be greater or smaller than the length of the straight portion 67C in other examples. The use of the horseshoe shape for the anode 67 shown in FIG. 6B can increase the aspect ratio of the anode 67 by a relatively larger factor than a corresponding increase in one dimension, measured linearly.

Anode 68 is an s-shaped anode with rounded corners. The anode 68 includes a first straight portion 68A, a first semi-ring-shaped portion 68B, a second semi-ring-shaped portion 68C, and a second straight portion 68D. The first semi-ring-shaped portion 68B extends in a curved direction opposite to that of the second semi-ring-shaped portion 68C, such that the portion 68B appears as the mirrored image of the portion 68C. The length “L1” of the anode 68 is measured along the straight end of the anode 68, such that the length “L1” is substantially equivalent to the difference between the inner radius “R1” and outer radius “R2” of the first semi-ring-shaped portion 68B. The width of the anode 68 can be measured along the outer perimeter of the first semi-ring-shaped portion 68B, the inner perimeter of the second semi-ring-shaped portion 68C, and the lengths “L2” and “L3” of the straight portions 68A and 68D.

The aspect ratio of the anode 68 can be in a range between (15:1) to (30:1), or higher. The aspect ratio of the anode 68 can vary on the basis of both the inner radius “R1” and outer radius “R2” of the first semi-ring-shaped portion 68B of the anode 68 and on the basis of both the inner radius “R3” and outer radius “R4” of the second semi-ring-shaped portion 68C. While the difference between “R1” and “R2” is preferably maintained to be the same as the difference between “R3” and “R4”, the size of the first semi-ring-shaped portion 68B can be larger or smaller than that of the second semi-ring-shaped portion 68C. Additionally, the lengths of the first straight portion 68A, the second straight portion 68D, or both can vary as compared to that shown. That is, the length “L2” of the straight portion 68A can be the same as or different than the length “L3” of the straight portion 68D in other examples.

By forming non-circular anodes, cathodes, and other features, the operating parameters of PIN diodes other than field build up can be optimized, such as thermal resistance, power handling, and series resistance. A number of design characteristics, including the lengths and widths of the anodes, the sizes and thicknesses of the individual layers, and the spread angles of the individual layers, can be individually tailored to achieve the optimal thermal resistance, power handling, and series resistance characteristics depending upon the particular application or use case of the PIN diodes under design.

As one example, limiter devices used in radar systems and front-end modules of transceivers can incorporate the concepts described herein to protect front-end receiver components, which are the most vulnerable to incident medium to high power. The power handling capability of the limiter devices as well as the insertion loss and leakage characteristics are critical for overall system performance. An ideal limiter would have zero insertion loss at low incident power, so as to not degrade the front-end receiver noise figure, and a flat leakage characteristic above a certain threshold of incident power. Unfortunately, the response of a PIN diode-based reflective limiter is not ideal and is intimately related to the physics of the diode (e.g., the thickness of the intrinsic region), the geometry of the diode, and the frequency of operation.

A common technique to improve the power handling capability of reflective limiter device is to use diodes developed with a thick intrinsic region layer. However, thickening the intrinsic region results in higher leakage characteristics that are undesirable to protect the front-end receiver. An alternative approach, based on the concepts described herein, is to work on the geometry of the diode as well as the topology of the front stage limiter to improve power handling capability, insertion loss, and frequency response, while maintaining the leakage characteristics offered by the choice of the thickness of the intrinsic region.

The use of a relatively thick intrinsic region in a multi-stage limiter works well for hybrid limiters. In that case, front-stage coarse limiting diode(s) having thicker intrinsic layers for better power handling capability can be paired with cleanup diode(s) on following stages having thinner intrinsic layers for lower flat leakage and P1 dB threshold level. Hybrid technology, however, has the disadvantage of very large device size and high cost.

Monolithic Microwave Integrated Circuit (MMIC) limiters can be highly integrated and low cost, but cannot benefit from the hybrid approach because all limiting diodes are implemented having the same intrinsic layer thickness, resulting in lower performance and power handling capability than hybrid limiters overall. The power handling capability of a reflective limiter is mostly determined by the thermal resistance of the front stage limiting PIN diode. In normal operation, only a small portion of the power is dissipated by the front stage limiting PIN diode while most of the incident power get reflected to the source. By reflecting the power rather than dissipating it, the limiter may potentially handle a large amount of power without damage. However, that small portion of power dissipated through the diode converts to heat mostly in the intrinsic and cathode regions or layers of the PIN diode where most of the resistance resides. The ability to remove the heat from the diode structure is quantified by the thermal resistance of the diode and determines the overall power handling capability of the limiter.

In that regard, PIN diodes having quadrilateral-shaped anodes offer superior performance to their equivalent devices having circular-shaped anodes. The simple heat spreading model described above for rectangular-shaped anodes shows significant improvement in device thermal resistance when compared to a standard circular-shaped anodes having a constant anode area and corresponding constant device capacitance. Additionally, the low frequency on-resistance of PIN diodes having rectangular-shaped anodes is significantly reduced as compared to circular-shaped anodes. Both the improvements in thermal resistance and electrical on-resistance at low frequency translate to an increased power handling capability of the diode, with thermal resistance dominating the improvement. In some cases, the aspect ratio of the anode can be optimized depending in part upon the frequency of operation, the bandwidth of operation of the circuit, and other factors.

When considering the design of a reflective PIN diode limiter, the active PIN diodes are in a shunt configuration and the insertion loss of the limiter is mostly imposed by the off-state capacitor of the diodes and the quality of the return to ground. The use of PIN diodes having rectangular-shaped anodes for reflective limiter applications offers an additional advantage when considering stacked diode configurations. The use of stacked diode(s) is well known to reduce the overall capacitance and therefore insertion loss of a reflective limiter. As the aspect ratio increases, the stack-up of diodes becomes much more compact allowing for a better return to ground, contributing to lower insertion loss and frequency bandwidth of the reflective limiter. Overall, optimizing the aspect ratio of the stacked rectangular diode for the front stage limiter design can result in improved power handling capability, improved insertion loss, and wider frequency response. The concepts described herein can lead to other improvements and advantages in other devices, fields, and applications.

FIG. 7 illustrates an example method of fabrication of diode structures according to various embodiments described herein. The method can be relied upon to fabricate or manufacture the PIN diode structure 10 shown in FIGS. 2A and 2B, the PIN diode structure 11 shown in FIG. 4, or related PIN diode structures, including PIN diode structures having anodes shaped as shown in FIGS. 6A and 6B. The method can be relied upon to fabricate or manufacture a NIP diode structure by switching steps 102 and 106. The representation of the method, as shown in FIG. 7, is not exhaustive. Additional steps can be relied upon before, after, or among the steps shown in FIG. 7 to fabricate the diode structures.

At step 100, the method includes providing a substrate. The substrate can be a GaAs substrate, for example, as described above. The substrate can be provided or sourced in any suitable way. The thickness of the substrate can range from approximately 4 mils (i.e., thousands of an inch) to 8 mils depending upon the purpose or application the PIN diode structures. For shunt diode fabrication, via holes can be etched under the diode and contacted with the N+ layer on the backside of the device. For series diode fabrication, the substrate is typically 8 mils, while for shunt diodes which require etched via holes, the substrate is etched down to 4 mils and vias are provided within the substrate in other process steps. Other thicknesses and configurations are within the scope of the embodiments.

At step 102, the method includes forming a cathode layer of a first doping type over the substrate. For example, step 102 can include forming or depositing an N+ layer on a top surface of the substrate provided at step 100. The N+ layer can be deposited on the substrate using epitaxial deposition. A low-pressure metalorganic vapor phase epitaxy (LP-MOVPE) technique can be used, for example, or another suitable technique. The N+ layer can be deposited to a thickness of about 2 μm, although other thicknesses are within the scope of the embodiments. In one example, the N+ layer can be deposited as GaAs semiconductor material with a first dopant, such as Si, although other types of dopants can be relied upon. In another example, the N+ layer can be deposited as AlGaAs semiconductor material with the first dopant. The N+ layer can be deposited with a well-defined orientation with respect to the underlying substrate using this approach.

At step 104, the method includes forming an intrinsic layer of semiconductor material over the cathode layer. For example, step 104 can include forming or depositing an intrinsic layer on a top surface of the N+ layer. The intrinsic layer can be disposed on the N+ layer using epitaxial deposition, for example, or another suitable technique. The intrinsic layer can be deposited to a thickness of about 2 μm, although other thicknesses are within the scope of the embodiments. The intrinsic layer 40 will establish the breakdown voltage and the capacitance of the PIN diode structure 10, at least in part. The intrinsic layer can be deposited as GaAs semiconductor material that is intrinsic, not doped, or not intentionally doped (i.e., without any dopant being intentionally added during the process step).

At step 106, the method includes forming an anode layer of semiconductor material of a second doping type over the intrinsic layer. For example, step 106 can include forming or depositing a P+ layer on a top surface of the intrinsic layer. The P+ layer can be deposited on the substrate using epitaxial deposition, for example, or another suitable technique. The P+ layer can be deposited to a thickness of about 0.8 μm, although other thicknesses are within the scope of the embodiments. In one example, the P+ layer can be deposited as AlGaAs semiconductor material with a second dopant, such as C, although other types of dopants can be relied upon. In another example, the P+ layer can be deposited as GaAs semiconductor material with the second dopant.

The AlGaAs semiconductor material has a wider band gap in the P+ layer, as compared to that of the intrinsic layer. This difference in band gap enables a suitable barrier height difference to be created, which enhances forward injection of holes from the P+ layer into the intrinsic layer and retards the back injection of electrons from the intrinsic layer into the P+ layer. The injected carriers of the junction are confined due to the band gap difference, effectively reducing the series resistance within the intrinsic region of the diode. Thus, there is an increased carrier concentration in the intrinsic region. This in turn reduces the resistance in the intrinsic region which enables reduction of insertion loss (e.g., at microwave frequencies) with no compromise in isolation.

At step 108, the method includes shaping at least one of the anode layer, the intrinsic layer, and the cathode layer into a quadrilateral shape. The shaping at step 108 can proceed in one or more masking and etching steps. At step 108, the method includes shaping the anode layer, the intrinsic layer, and the cathode layer. The shaping at step 108 can proceed in one or more masking and etching steps. For example, the process can include coating a photoresist or hard mask over the anode layer and patterning the mask using photolithography to selectively remove areas in the mask. According to the embodiments described herein, the remaining areas can be shaped as a quadrilateral, such as a rectangle or a square. Alternatively, the remaining areas can include any of the shapes shown in FIGS. 6A, 6B, or others consistent with the embodiments.

The etching at step 108 can also include etching semiconductor material away around the mask. The etching can be controlled or directed to obtain a certain etch profile using any suitable semiconductor manufacturing technique(s). In one embodiment, a quadrilateral-shaped anode can be obtained with a vertical (or near-vertical etch) profile. In another embodiment, a quadrilateral-shaped anode can be obtained with a tapered profile, for example, to arrive at the spread angles described herein. In some cases, the shaping at step 108 can proceed in several iterations of masking and etching, sometimes with different etch profiles for different, separate etching steps. Referencing FIG. 4, the P+ layer 51 can be etched down to form a quadrilateral shape at a first tapered profile, the intrinsic layer 41 can be etched down to form the quadrilateral shape at a second tapered profiled, and the N+ layer 31 can be etched down to form the quadrilateral shape at a third tapered profile. The first, second, and third tapered profiles can be the same. Alternatively, one or more of the first, second, and third tapered profiles can be different than each other. In that way, the spread angle “α2” can be formed to have a different value than the spread angle “α1.”

Additional process steps can be relied upon to form a larger integrated circuit device including diodes, capacitors, inductors, resistors, and layers of metal to electrically interconnect the circuit elements together to form switches, limiters, and other devices. Additionally, although the process shown in FIG. 7 is described as being formed on a GaAs substrate, with layers of doped GaAs and AlGaAs, the concepts described herein are not limited to diodes formed from any particular type(s) of semiconductor materials. Instead, the use of anodes having square, rectangular, or other shapes, in extension to round or circular shapes, can be applied to form diodes from other type(s) of semiconductor materials to achieve advantages similar to those described herein.

While an AlGaAs semiconductor material device and process has been described for the formation of a heterojunction PIN diodes, a variety of Group III-V materials can be employed as bandgap modifiers, including Indium Gallium Phosphide (InGaP), Indium phosphide (InP), as well as other Group III-V materials. Furthermore, PIN diode structures may not be limited to Group III-V compounds, but may include Group II-VI or Group IV-IV materials, including Silicon (Si), Germanium (Ge), Carbon (C), SiGe, SiC, or SiGeC materials, for example. In these cases, the band gap of the anode should be greater than the band gap of the I-region. Further, that lowering the bandgap E_{g} in the I-region relative to the P region achieves the same result, namely that of confining charge carriers by building a sufficiently large barrier between the P and I regions.

The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

Therefore, the following is claimed:

1. A PIN diode structure comprising:
an N-type layer of gallium arsenide (GaAs) semiconductor material comprising a first dopant;
an intrinsic layer of GaAs semiconductor material formed on the N-type layer; and
a P-type layer of GaAs semiconductor material comprising a second dopant and being formed on the intrinsic layer, wherein:
the top surface perimeter of the P-type layer comprises a width W and a length L;
an aspect ratio of the P-type layer is defined as a ratio of W and L;
W is greater than L or L is greater than W such that the aspect ratio of the P-type layer is 2 or greater; and
the top surface perimeter of the of the P-type layer comprises a first straight portion, a first semi-ring-shaped portion, a second semi-ring-shaped portion, and a second straight portion.

2. The PIN diode structure according to claim 1, wherein the P-type layer comprises a P-type layer of aluminum gallium arsenide (AlGaAs) semiconductor material.

3. The PIN diode structure according to claim 1, wherein:
the P-type layer comprises an anode of the PIN diode structure; and
the N-type layer comprises a cathode of the PIN diode structure.

4. The PIN diode structure according to claim 1, wherein the aspect ratio of the P-type layer is 3 or greater.

5. The PIN diode structure according to claim 1, wherein the aspect ratio of the P-type layer is 4 or greater.

6. The PIN diode structure according to claim 1, wherein the first dopant is Silicon and the second dopant is Carbon.

7. The PIN diode structure according to claim 1, further comprising a substrate, wherein the N-type layer, the intrinsic layer, and the P-type layer are formed on the substrate.

8. The PIN diode structure according to claim 1, wherein the first straight portion and the first semi-ring-shaped portion are mirrored as compared to the second semi-ring-shaped portion and the second straight portion.

9. The PIN diode structure according to claim 1, wherein a length of the first semi-ring-shaped portion is different than a length of the second semi-ring-shaped portion.

10. The PIN diode structure according to claim 1, wherein a length of the first straight portion is different than a length of the second straight portion.

11. A diode structure comprising:
an anode layer of aluminum gallium arsenide (AlGaAs) semiconductor material of a first doping type;
a cathode layer of gallium arsenide (GaAs) semiconductor material of a second doping type; and
an intrinsic layer of GaAs semiconductor material between the anode layer and the cathode layer, wherein:
a top surface perimeter of the anode layer comprises a first straight portion and a first curved portion.

12. The diode structure according to claim 11, wherein the top surface perimeter of the anode layer comprises the first straight portion, the first curved portion, a second straight portion, and a second curved portion.

13. The diode structure according to claim 12, wherein the first straight portion and the first curved portion are mirrored as compared to the second curved portion and the second straight portion.

14. The diode structure according to claim 11, wherein:
the top surface perimeter of the anode layer comprises a width W and a length L;
an aspect ratio of the anode layer is defined as a ratio of W and L;
W is greater than L or L is greater than W such that the aspect ratio of the anode layer is 2 or greater.

15. The diode structure according to claim 14, wherein the aspect ratio of the anode layer is 3 or greater.

16. The diode structure according to claim 11, wherein:
the anode layer comprises a P-type layer of aluminum gallium arsenide (AlGaAs) semiconductor material; and
the cathode layer comprises an N-type layer of gallium arsenide (GaAs) semiconductor material.

17. A diode structure comprising:
an anode layer of semiconductor material of a first doping type;
a cathode layer of semiconductor material of a second doping type; and
an intrinsic layer semiconductor material between the anode layer and the cathode layer, wherein:
a top surface perimeter of the anode layer comprises a first straight portion and a first curved portion.

18. The diode structure according to claim 17, wherein the top surface perimeter of the anode layer comprises the first straight portion, the first curved portion, a second straight portion, and a second curved portion.

19. The diode structure according to claim 17, wherein:
the top surface perimeter of the anode layer comprises a width W and a length L;
an aspect ratio of the anode layer is defined as a ratio of W and L;
W is greater than L or L is greater than W such that the aspect ratio of the anode layer is 2 or greater.

20. The diode structure according to claim 17, wherein:
the anode layer comprises a P-type layer of aluminum gallium arsenide (AlGaAs) semiconductor material; and
the cathode layer comprises an N-type layer of gallium arsenide (GaAs) semiconductor material.
